(19) United States
(12) Patent Application Publication
(10) Pub. No.: US 2008/0204102 A1
(43) Pub. Date: Aug. 28, 2008

(54) METHOD TO REGULATE PROPAGATION DELAY OF CAPACITIVELY COUPLED PARALLEL LINES

(75) Inventor: Harold Brett Meadows, Colorado Springs, CO (US)

Correspondence Address: HOGAN & HARTSON LLP, ONE TABOR CENTER, SUITE 1500, 1200 SEVENTEENTH ST, DENVER, CO, 80202, US

(73) Assignee: PROMOS TECHNOLOGIES PTE.LTD.

(21) Appl. No.: 11/679,632

(22) Filed: Feb. 27, 2007

(51) Int. Cl. H03H 11/26

(52) U.S. Cl. 327/261

(57) ABSTRACT

Capacitive coupling between adjacent parallel lines in an integrated circuit is made more uniform and allows for better timing control of the lines through the use of inverters placed on one or both of the adjacent interconnect lines. By staggering the placement of inverters along adjacent lines, constructive and destructive coupling terms between the lines are balanced out. The propagation delay through the inverter is made less than the propagation delay through one half of the line length of the corresponding line.

### BACKGROUND OF THE INVENTION

The present invention relates generally to integrated circuits, and more particularly, to regulating the propagation delay in adjacent parallel metal lines in a metal interconnect layer of an integrated circuit.

In an integrated circuit, two parallel signals running next to each other in adjacent interconnect lines tend to either reinforce each other, if both are driven to the same polarity at the same time, or impede each other if driven to opposite polarities at the same time. The problem with signals reinforcing each other on adjacent capacitively coupled lines is that the signals can be “too fast”. Conversely, the problem with signals impeding each other on adjacent capacitively coupled lines is that the signals can be “too slow”. A signal is “too fast” or “too slow”, in comparison to a signal on a line that is capacitively coupled to another signal on a line that is not moving at the same time.

Consider two adjacent parallel lines of length L as shown in FIG. 1. Two signals are carried on Line A and Line B. The capacitance between Lines A and B is represented by two equal lumped values. Thus, the terms C₁ and C₂ each represent the capacitance associated with half of the line length. In FIG. 1:

C₁=C₂ [1]

C₁+C₂=C_{TOTAL} [2]

Now, consider line A to be at zero volts potential and line B to be at zero volts potential. Assume that Line A is the signal of interest. If Line B is held at zero volt potential and Line A is switched from zero volts to another potential, Line B is a capacitive load to Line A. Now, if instead of holding Line B at zero volts potential and having it transition at the same time as Line A, in the same polarity direction of Line A, Line B acts to capacitively couple Line A to the new potential. This effectively cancels the capacitance terms between Line A and Line B. If, on the other hand, Line B transitions in the opposite direction of Line A, Line B will try to couple Line A in opposition to the polarity that Line A is trying to achieve. This will slow Line A down.

Prior art techniques include shielding a signal line with adjacent parallel lines of the same material and ensuring that the shield is either tied to a static supply or tied to a signal that is not moving during the transition time of the signal of interest. While this technique is effective for dealing with capacitive coupling between adjacent signal lines, it increases the cost of the integrated circuit. Because additional lines are used for shielding, more space is required in the layout/area of the chip. Referring now to FIG. 2, signal Line A and signal Line B are shielded from each other through the use of static Line C, which is coupled to a static voltage such as ground, VCC, or the like. Capacitors C₁ and C₂ represent the total coupling capacitance of Line A to Line C and capacitors C₃ and C₄ represent the total coupling capacitance of Line B to Line C.

What is desired, therefore, is a way to regulate the various delays caused by the coupling capacitance of adjacent interconnect lines in an integrated circuit, without the added circuit area and expense of additional shield lines.

### SUMMARY OF THE INVENTION

The present invention makes the capacitive coupling between adjacent parallel lines more uniform and allows for better timing control of said lines through the use of inverters placed on one or both of the adjacent interconnect lines. By staggering the placement of inverters along adjacent lines, constructive and destructive coupling terms between the lines are balanced out.

The circuit and method of the present invention ensures that both cases of capacitive coupling are used in a single interconnect line or portion of a line, which results in a regulated propagation delay. This is done by inverting one of the lines halfway down its length L. In the static condition where Line B is not moving, both sides of the inverter are static and the capacitances associated with each side of the inverter looks like a static capacitive load to Line A. If Line B transitions, however, one side of the inverter, or the capacitance associated with one side of the inverter will be a reinforcing term while the other side of the inverter will be an impeding term. This is true regardless of direction of transitions on Line B.

An important constraint of the present invention is that the propagation delay through the inverter should be less than the propagation delay through one half of the line length, i.e. L/2, for best performance.

If desired, additional input and output inverter circuits can be coupled to the adjacent interconnect lines to provide the proper polarity inputs and outputs as required. Additionally, each segment of the coupled lines can include an inverter, and the pattern of the inverters can be staggered. Further, the inverter can be replace by other inverting logic gates such as an inverting bi-directional tri-state driver, or other logic gate.

One advantage of the present invention is that it requires less integrated circuit layout area than prior art shielded techniques because fewer lines are required.

### BRIEF DESCRIPTION OF THE DRAWINGS

The aforementioned and other features and objects of the present invention and the manner of attaining them will become more apparent and the invention itself will be best understood by reference to the following description of a preferred embodiment taken in conjunction with the accompanying drawings, wherein:

FIG. 1 is a diagram of two adjacent interconnect signal lines showing the coupling capacitance between the two lines as two lumped capacitors according to the prior art;

FIG. 2 is a diagram of two adjacent interconnect signal lines shielded from one another with the use of a static line according to the prior art;

FIG. 3 is a diagram of two adjacent interconnect signal lines using an inverter inserted into one of the signal lines according to the present invention;

FIG. 4 is a diagram of two adjacent interconnect signal lines using an inserted inverter and also including input and output inverter circuits according to the present invention;

FIG. 5 is a diagram of two adjacent interconnect signal lines wherein a plurality of line segments each include two adjacent signal line portions and an inverter, wherein the line segments include a staggered inverter pattern; and

FIG. 6 is a diagram of two adjacent interconnect signal lines using an inverting bi-directional tri-state driver inserted into one of the signal lines according to the present invention.

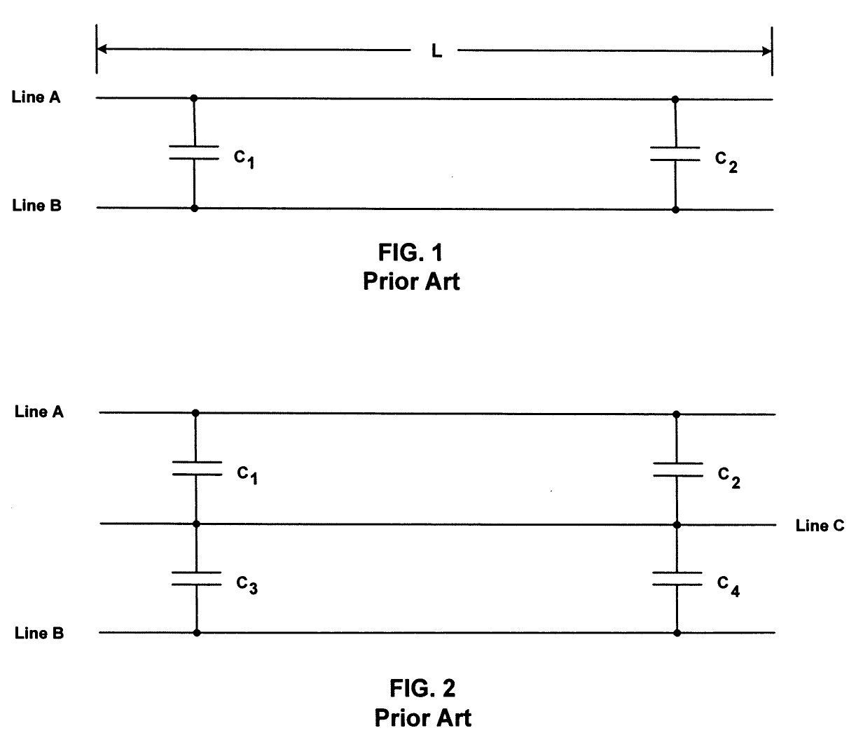

### DETAILED DESCRIPTION

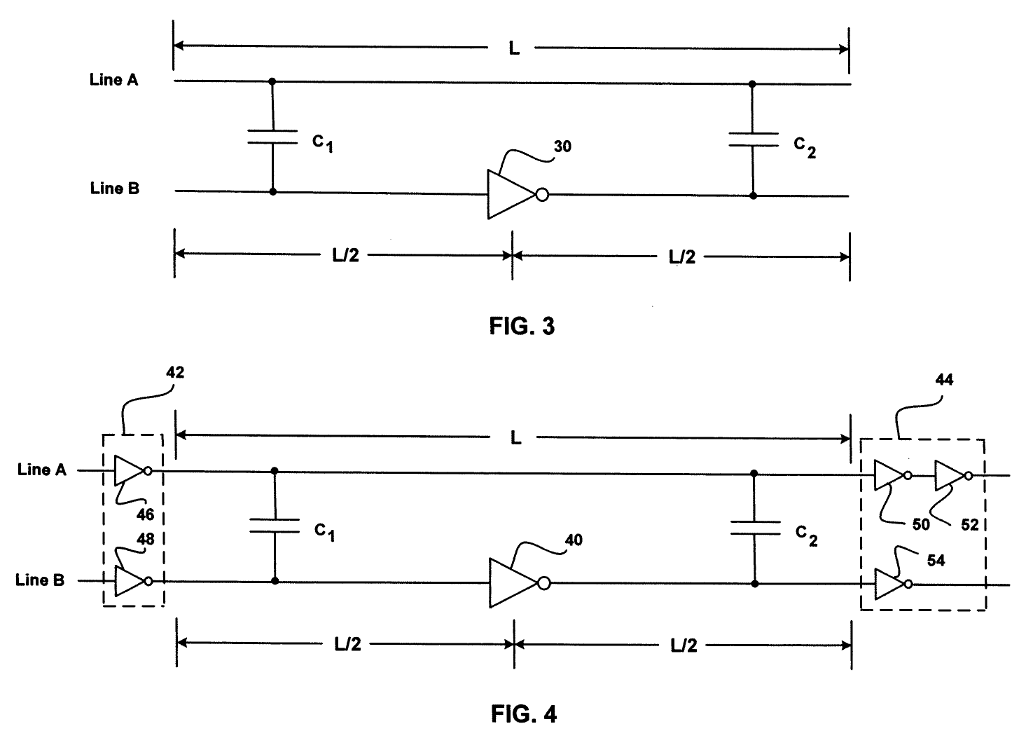

Referring now to FIG. 3, a pair of capacitively coupled parallel lines having a regulated propagation delay include a first line designated Line A having a length L, a second line designated Line B having a length L, and an inverter 30 interposed between first and second portions of the second line, Line B. The first portion of the second line has a length of about L/2. The second portion of the second line also has a length of about L/2. The addition of inverter 30 ensures that the first and second portions of the second line are oppositely capacitively coupled to the first line, regardless of the polarity of the signals on the first and second lines. In this way, the total delay through the coupled lines Line A and Line B is regulated.

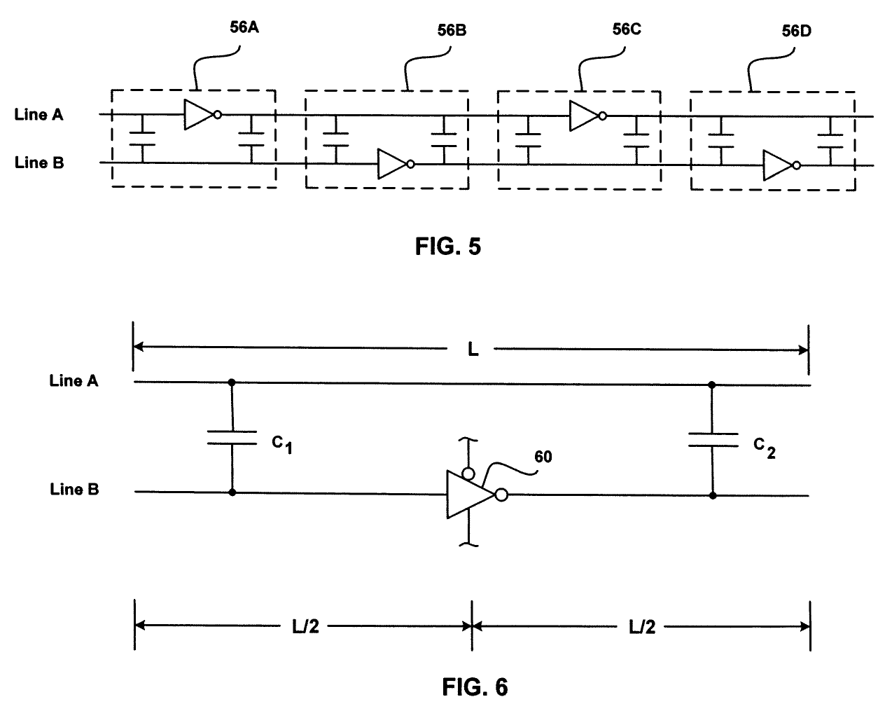

An important constraint of the present invention is that the propagation delay through the inverter 30 should be less than the propagation delay through one half of the line length, i.e. L/2, for best performance. Related to this constraint is an additional design rule in that when the delay through L/2 equals the delay through the inverter in a running length of interconnect, and additional inverter should be placed to gain the full benefit according to the present invention. A staggered pattern including multiple inverters in a single interconnect is shown and described in further detail below with respect to FIG. 5.

Referring now to FIG. 4, the input and output polarities of the signals on Line A and Line B can be adjusted if desired through the use of additional inverter circuitry. Input inverter circuit 42 is coupled to the inputs of Line A and Line B. Input inverter circuit 42 includes inverter 46 coupled to Line A and inverter 48 coupled to Line B. Output inverter circuit 44 is coupled to the outputs of Line A and Line B. Output inverter circuit 44 includes inverters 50 and 52 coupled to Line A and inverter 54 coupled to Line B. While a particular arrangement of inverters is shown in FIG. 4, it is apparent to those skilled in the art that any number of inverters can be used as desired for a particular application.

Numerous variations of the basic circuit shown in FIG. 3 can be made and used on an integrated circuit, especially with long interconnect lines. For example, in FIG. 5, a pair of capacitively coupled parallel lines Line A and Line B having a regulated propagation delay, wherein the coupled parallel lines include parallel line segments 56A-56D. Each parallel line segment 56A-D includes a first line having a length L, a second line having a length L, and an inverter interposed between first and second portions of either the first line or the second line. The first and second portions have a length of about L/2. As shown in FIG. 5, the parallel line segments have a staggered inverter pattern.

Another embodiment of the present invention is shown in FIG. 6. In this embodiment a bi-directional inverting tri-state driver 60 is used instead of an inverter as previously described. This allows for similar propagation control of a bi-directional bus/signal. The embodiment of FIG. 6 also illustrates that any signal inverting element can be used in place of the previously described inverters. Other such logic gates could include NAND gates and the like.

While there have been described above the principles of the present invention in conjunction with specific implementations and device processing technology, it is to be clearly understood that the foregoing description is made only by way of example and not as a limitation to the scope of the invention. Particularly, it is recognized that the teachings of the foregoing disclosure will suggest other modifications to those persons skilled in the relevant art. Such modifications may involve other features which are already known per se and which may be used instead of or in addition to features already described herein. Although claims have been formulated in this application to particular combinations of features, it should be understood that the scope of the disclosure herein also includes any novel feature or any novel combination of features disclosed either explicitly or implicitly or any generalization or modification thereof which would be apparent to persons skilled in the relevant art, whether or not such relates to the same invention as presently claimed in any claim and whether or not it mitigates any or all of the same technical problems as confronted by the present invention. The applicants hereby reserve the right to formulate new claims to such features and/or combinations of such features during the prosecution of the present application or of any further application derived therefrom.

We claim:

1. A pair of capacitively coupled parallel lines having a regulated propagation delay comprising:
a first line having a length L;
a second line having a length L; and
an inverter interposed between first and second portions of the second line, wherein the propagation delay through the inverter is less than the propagation delay through either the first of second line.

2. The pair of capacitively coupled parallel lines as in claim 1 wherein the first portion of the second line has a length of about L/2.

3. The pair of capacitively coupled parallel lines as in claim 1 wherein the second portion of the second line has a length of about L/2.

4. The pair of capacitively coupled parallel lines as in claim 1 further comprising an input inverter circuit coupled to at least one of the coupled parallel lines.

5. The pair of capacitively coupled parallel lines as in claim 4 wherein the input inverter circuit comprises at least one inverter coupled to an input of the first line and at least one inverter coupled to an input of the second line.

6. The pair of capacitively coupled parallel lines as in claim 1 further comprising an output inverter circuit coupled to at least one of the coupled parallel lines.

7. The pair of capacitively coupled parallel lines as in claim 6 wherein the output inverter circuit comprises at least one inverter coupled to an output of the first line and at least one inverter couple to an output of the second line.

8. A method for regulating the propagation delay of a pair of capacitively coupled parallel lines comprising:
providing a first line having a length L;
providing a second line having a length L; and
interposing an inverting logic gate between first and second portions of the second line, wherein the propagation delay through the inverting logic gate is less than the propagation delay through either the first of second line.

9. The method of claim 8 wherein the first portion of the second line has a length of about L/2.

10. The method of claim 8 wherein the second portion of the second line has a length of about L/2.

11. The method of claim 8 further comprising coupling an input inverter circuit to at least one of the coupled parallel lines.

12. The method of claim 11 wherein coupling the input inverter circuit comprises coupling at least one inverter to an input of the first line and coupling at least one inverter to an input of the second line.

13. The method of claim 8 further comprising coupling an output inverter circuit to at least one of the coupled parallel lines.

14. The method of claim 13 wherein coupling the output inverter circuit comprises coupling at least one inverter to an output of the first line and coupling at least one inverter to an output of the second line.

15. A pair of capacitively coupled parallel lines having a regulated propagation delay, wherein the coupled parallel lines include parallel line segments, each parallel line segment comprising:
a first line having a length L;
a second line having a length L; and
an inverter interposed between first and second portions of either the first line or the second line, wherein the propagation delay through the inverter is less than the propagation delay through either the first of second line.

16. The pair of capacitively coupled parallel lines as in claim 15 wherein the first portion has a length of about L/2.

17. The pair of capacitively coupled parallel lines as in claim 15 wherein the second portion has a length of about L/2.

18. The pair of capacitively coupled parallel lines as in claim 15 wherein the parallel line segments have a staggered inverter pattern.

19. The pair of capacitively coupled parallel lines as in claim 15 further comprising an input inverter circuit coupled to at least one of the coupled parallel lines.

20. The pair of capacitively coupled parallel lines as in claim 15 further comprising an output inverter circuit coupled to at least one of the coupled parallel lines.

21. A pair of capacitively coupled parallel lines having a regulated propagation delay, wherein the coupled parallel lines include parallel line segments, each parallel line segment comprising:
a first line having a length L;
a second line having a length L; and
an inverting element interposed between first and second portions of either the first line or the second line, wherein the propagation delay through the inverter is less than the propagation delay through either the first of second line.

22. The pair of capacitively coupled parallel lines as in claim 21 wherein the inverting element comprises a tri-state driver.

23. The pair of capacitively coupled parallel lines as in claim 21 wherein the inverting element comprises a bi-directional inverting tri-state driver.

24. The pair of capacitively coupled parallel lines as in claim 21 wherein the inverting element comprises a NAND gate.

25. The pair of capacitively coupled parallel lines as in claim 21 wherein the inverting element comprises a logic gate.
